(19) United States
(12) Patent Application Publication
(10) Pub. No.: US 2026/0206142 A1
(43) Pub. Date: Jul. 16, 2026

(54) Component Carrier With Reinforcing Portion, and Manufacturing Method

(71) Applicant: AT&S Austria Technologie & Systemtechnik Aktiengesellschaft, Leoben (AT)

(72) Inventors: Artan BAFTIRI, Graz (AT); Markus WENINGER, Leoben (AT)

(21) Appl. No.: 19/134,742

(22) PCT Filed: Nov. 29, 2023
(86) PCT No.: PCT/EP2023/083536

§ 371 Date: Jun. 1, 2025

(30) Foreign Application Priority Data
Dec. 2, 2022 (CN) 202211541256.4

(51) Int. Cl. H05K 1/185; H05K 1/02; H05K 1/183; H05K 3/30

(52) U.S. Cl. CPC H05K 1/185; H05K 1/0271; H05K 1/183; H05K 3/30

(57) ABSTRACT

A component carrier including
i) a central structure having a recess extending from a main surface through the thickness of the central structure;
ii) at least one component arranged in the recess;
iii) an encapsulant material in the recess and at least partially encapsulating the at least one component; and
iv) a reinforcing portion, wherein the reinforcing portion is associated with the external side of the encapsulant material.

### CROSS REFERENCE TO RELATED APPLICATIONS

This application is a national stage application, filed under 35 U.S.C. § 371, of International Patent Application No. PCT/EP2023/083536, filed on Nov. 29, 2023, claiming priority of the filing date of the Patent Application No. 202211541256.4, filed on Dec. 2, 2022, with the China National Intellectual Property Administration, the disclosures of which are hereby incorporated by reference herein in their entirety.

### TECHNICAL FIELD

The disclosure relates to a component carrier. Further, the disclosure relates to a method of manufacturing said component carrier.

Accordingly, the disclosure may relate to the technical field of component carriers such as printed circuit boards and IC substrates.

### TECHNICAL BACKGROUND

In the context of growing product functionalities of component carriers equipped with one or more electronic components and increasing miniaturization of such electronic components as well as a rising number of electronic components to be mounted on the component carriers such as printed circuit boards, increasingly more powerful array-like components or packages having several electronic components are being employed, which have a plurality of contacts or connections, with ever smaller spacing between these contacts. Removal of heat generated by such electronic components and the component carrier itself during operation becomes an increasing issue. Also, an efficient protection against electromagnetic interference (EMI) becomes an increasing issue. At the same time, component carriers shall be mechanically robust and electrically and magnetically reliable so as to be operable even under harsh conditions.

In particular, embedding a (active/passive electric) component into a component carrier may still be considered a challenge.

FIG. 5 illustrates a conventional example of a circuit board 200 with an embedded component 210. The circuit board 200 comprises a stack with a core 203, dielectric layers 260 and electrically conductive connections 204. The component 210 is placed into a cavity of the core 203 and is further embedded by a mold 220.

However, in particular in case of comparably large components, a component carrier may be prone to warpage and undulation, shown in this example by a strongly curved upper main surface 280 of the circuit board 200.

FIG. 6A, FIG. 6B, FIG. 6C, FIG. 6D, and FIG. 6E illustrate a conventional example of embedding the component 210 into the core 203 of the circuit board 200.

In FIG. 6A a cavity 205 (here a through hole) is provided in the core structure 203.

In FIG. 6B a temporary carrier 206, e.g. an adhesive foil, is arranged below the core structure 203 and the cavity 205.

In FIG. 6C the component 210 is placed onto the adhesive foil 206 and within the cavity 205.

In FIG. 6D the component 210 is embedded within the cavity 205 by the same material as the core structure 203.

In FIG. 6E it is schematically shown that undesired voids 208 are formed by the embedding process in the former cavity 205.

Conventional embedding methods may therefore lead to a component carrier being prone to undulation and warpage. For example, there may be undulation on the component region due to thickness matching during embedding, e.g. due to the filling material flowing into the space between the component carrier and the component. For example, the filling material or the material above the filling material comprises a filler, for example spheres, such as ABF® material. ABF is a registered mark of the Ajinomoto Co., Inc. of Tokyo, Japan. Undulation and warpage may further hamper the quality of electrically conductive layer structures, e.g. copper traces, arranged on the core structure. The issues of warpage and/or undulation may in particular arise in the case of a comparably large component and/or a comparably thick core structure.

### SUMMARY

There may be a need to embed a component into a component carrier in an efficient and reliable manner, in particular so that the component carrier is resilient against undulation and warpage.

A component carrier and a manufacturing method are provided.

According to an embodiment of the disclosure, there is described a component carrier, comprising: i) a central structure (e.g. a core (layer structure) or a multilayer structure) having a recess (e.g. a blind hole or a through hole), the recess extending from a main surface (of the central structure) through the thickness (along vertical direction z) of the central structure; ii) at least one (passive or active electronic) component arranged in the recess; iii) an encapsulant material (e.g. a resin), wherein the encapsulant material is provided in the recess and at least partially encapsulates the at least one component (within the recess) (in particular wherein the encapsulant material is different from the material of the central structure); and iv) a reinforcing portion (e.g. a metal layer), wherein the reinforcing portion is associated (e.g. by a direct or indirect contact or by being part of) with an external side (in particular an upper/lower main surface external side) of the encapsulant material.

According to a further embodiment of the disclosure, there is described a method of manufacturing a component carrier, the method comprising: i) providing a central structure (e.g. a thick core) having a recess, wherein the recess extends from a main surface through the thickness of the central structure; ii) arranging at least one a component in the recess; iii) encapsulating the component by providing encapsulant material in the recess; and iv) providing a reinforcing portion, wherein the reinforcing portion is associated with an external side of the encapsulant material.

### OVERVIEW OF EMBODIMENTS

In the context of the present document, the term “central structure” may in particular refer to a layer structure within a component carrier layer stack, wherein the central structure is at least partially arranged within a central position (of the stack/component carrier). For example, when the component carrier layer stack comprises three layer structures, the sandwiched layer structure in the middle may be considered as the central structure. Yet, the central structure may not always have to be exactly in the middle. Rather, the central structure may have a stabilizing functionality for the stack. For example, the central structure may be configured more robust and/or with a greater thickness than other layer structures in the stack.

In an example, the central structure may be configured as a core (layer structure). Such a core may comprise (fully) cured material during the manufacture, while other layer structures are often (at least partially) uncured during the manufacture (prepregs). The core may comprise a reinforced material, e.g. glass-fiber reinforced epoxy resin (such as FR4). In an example, the core may be thicker than (most) other layer structures.

In another example, the central structure may be configured as a multilayer structure (within a stack).

In the context of the present document, the term “encapsulant material” may be considered as a material suitable to (at least partially) encapsulate a component within a recess. In an example, the encapsulant material may cover the component in the recess (arranged on top of the recess). In a further example, the encapsulant material may cover the sides of the component in the recess. While in one example, the encapsulant material fully encapsulates the component, in another example the encapsulant material may not cover (an external side of the component, where there is placed) an electrical connection area of the component. In an embodiment, the encapsulant material may comprise a typical component carrier material, for example a resin. Preferably, the encapsulant material is not further reinforced, e.g. by fibers or spheres. Yet, in an example, the encapsulant material may be reinforced fiber-free, e.g. by spheres such as ABFR. During application of the encapsulant material, the material may be at least materially uncured. In the final component carrier, however, the encapsulant material may be cured.

In the context of the present document, the term “reinforcing portion” may in particular refer to a portion suitable to reinforce the above-described encapsulant material (within the recess). In a preferred example, the reinforcing portion may be configured as a reinforcing layer (structure). Such a reinforcing layer may at least partially cover an external side of the encapsulant material, thereby reinforcing it. In an embodiment, the reinforcing portion may be configured as an electrically conductive layer structure, for example comprising a metal such as copper. According to another embodiment, the reinforcing portion is configured as a portion of the encapsulant material which portion extends beyond the main surface of the central structure (see FIG. 4). While in one embodiment, the reinforcing portion may cover a center of the external side of the encapsulant material, in another embodiment, the reinforcing portion may cover the peripheral portion(s) of said external side. In an example embodiment, the reinforcing portion is arranged on the external side of the encapsulant material that is opposite to the (exposed) connection area of the encapsulated component.

In the context of the present document, the term “associated” may in particular refer to the circumstance that the reinforcing portion is coupled to an external side of the encapsulant material. The reinforcing portion may hereby, by being directly connected to the external side (e.g. to the upper main surface) thereby cover (at least partially) the external side. Further, the reinforcing portion may be indirectly coupled to the external side, for example when an additional layer such as an electrically insulating layer structure is arranged in between the reinforcing portion and the encapsulant material. In a further example, the reinforcing portion may be a specific part of the encapsulant material at the external side, preferably a portion that vertically extends beyond the central structure main surface(s).

In the context of the present document, the term “component carrier” may particularly denote any support structure which is capable of accommodating one or more components thereon and/or therein for providing mechanical support and/or electrical connectivity. In other words, a component carrier may be configured as a mechanical and/or electronic carrier for components. In particular, a component carrier may be one of a printed circuit board, an organic interposer, a metal core substrate, an inorganic substrate and an IC (integrated circuit) substrate.

In the context of the present document, the term “IC substrate” may particularly denote a small component carrier. An IC substrate may be a, in relation to a PCB, comparably small component carrier onto which one or more components may be mounted and that may act as a connection medium between one or more chip(s) and a further PCB. More specifically, an IC substrate can be understood as a carrier for electrical connections or electrical networks as well as component carrier comparable to a printed circuit board (PCB), however with a considerably higher density of laterally and/or vertically arranged connections. Lateral connections are for example conductive paths, whereas vertical connections may be for example drill holes. These lateral and/or vertical connections are arranged within the substrate and can be used to provide electrical, thermal and/or mechanical connections of housed components or unhoused components (such as bare dies), particularly of IC chips, with a printed circuit board or intermediate printed circuit board. In an example, an IC substrate may be seen as an interposer, for example between electronic components and a printed circuit board.

In the present context, an IC substrate should not be understood as only any substrate suitable to bear an IC. Instead, the term “IC substrate” may be a technically established term for a specific, high-density PCB that comprises common PCB materials. A silicon-based substrate for example may not be considered an IC substrate in the present context.

According to an example embodiment, a component may be embedded into a component carrier in an efficient and reliable manner, in particular so that the component carrier is resilient against undulation and warpage, when a reinforcing portion is applied and associated with an external side of the encapsulant material (which encapsulates the component in a recess of the component carrier central structure).

Conventionally (see e.g. FIGS. 5 and 6), a component is embedded in a core cavity by dielectric material and is afterwards (together with the core) sandwiched between further dielectric layers. The known process may lead to undulation and warpage, in particular in case of large components, as described above.

It has now been found by the inventors, however, that a highly reliable and robust component carrier may be provided, when the encapsulant material (with the component therein) is reinforced by a specific reinforcing portion. For example, the reinforcing portion can be configured as a reinforcing layer (e.g. metal) that at least partially (directly) covers the encapsulant material. Alternatively, the reinforcing portion may be configured as a part of the encapsulant material that extends vertically beyond the central structure main surface(s).

Thereby, the component carrier is stabilized in an efficient manner, so that undesired bending can be prevented. The reinforcing portion may be implemented into existing production lines in a straightforward manner, for example as part of the electrically conductive layer structures or by grinding in a specific manner the encapsulant material.

If warpage/undulation can be efficiently avoided, the quality of the component carrier may be highly improved. Specifically, electrical connection may be done in a significantly more reliable manner.

### EXAMPLE EMBODIMENTS

According to an embodiment, the central structure comprises a core layer structure, in particular thick core, more in particular with a thickness in the range between 500 μm and 2 mm. Such a core may be considered as an especially thick core which may be applied for specific applications. Thereby, an advantage may be provided that also in the case of a thick core structure, a reliable and robust component carrier may be manufactured.

According to a further embodiment, the recess is configured as a blind hole, preferably with a height greater than 80% of the central structure thickness (along z). According to a further embodiment, the recess is configured as a through hole.

According to a further embodiment, the reinforcing portion comprises a reinforcing layer, and the reinforcing layer (or the reinforcing portion) comprises a stiffness being higher than the stiffness of the encapsulant material. This may provide the advantage that the reinforcing portion may provide an efficient stabilization effect for the encapsulant material and the component carrier as a whole. In an example, a Young modulus of the reinforcing portion/layer is 60 GPa or larger. In a further example, the Young modulus of the reinforcing portion/layer is larger than the Young modulus of the encapsulant material. In a specific example, the Young modulus of copper is 117 GPa and that of core material is 30 GPa.

According to a further embodiment, the recess defines a first frontal area (at the main surface where the recess extends, defined from the frontal view of one of the main surfaces of the central structure) and the reinforcing layer defines a second frontal area (at the same central structure main surface where the first frontal area is defined). Said second frontal area can have an area value of at least 60%, in particular at least 80%, more in particular at least 90%, more in particular 100% or more, with respect to the area value of the first frontal area.

This may provide the advantage that the reinforcing portion covers an area large enough to enable a highly efficient stabilization. The frontal areas may be viewed from a top view, i.e. along the z-axis. In other words, said viewing direction may be along a normal vector of the component carrier main surface that is defined along its directions of main extension (along x- and y-axis).

According to a further embodiment, the reinforcing layer comprises or consists of metal, in particular copper. This may provide the advantage that a highly suitable reinforcing material may be directly implemented into the manufacturing process. Providing metal, in particular copper, e.g. by plating, is highly common in component carrier manufactures. Hence, the reinforcing portion may be provided in a straightforward manner within an established manufacturing process.

Even though conventional examples (see FIG. 5) may describe an electrical connection to connection areas of the embedded component, these electrical connection (e.g. traces) are rather thin and do not provide the technical effect of stabilizing the component carrier as the described reinforcing portion. In an example, the reinforcing portion (in particular comprising a metal such as copper) comprises a thickness of 5 μm or larger, in particular 15 μm or larger, more in particular in the range 15 μm to 25 μm.

According to a further embodiment, the reinforcing layer comprises or consists of a dielectric material that is stiffer than the material of the encapsulant material and/or the central structure material. The dielectric reinforcing material may be inorganic or organic.

According to a further embodiment, the reinforcing portion (material) comprises a filler material, for example fibers or spheres. Examples may include glass or carbon or metal fibers/spheres.

According to a further embodiment, the reinforcing portion is configured as part of the encapsulant material associated with an external side, in particular a part of the encapsulant material that vertically extends beyond the main surface(s) of the central structure. In an example, a part or the entire portion of the encapsulant material that vertically extends beyond the main surface(s) may be chemically and/or physically treated e.g. by temperature in order to make the exposed surface stiffer.

According to a further embodiment, the reinforcing layer is (at least partially) in contact with the encapsulant material. In particular, the whole main surface of the reinforcing layer is in contact with the encapsulant material. This may provide the advantage that the reinforcing effect may be directly applied onto the encapsulant portion, thereby being especially robust.

According to a further embodiment, the reinforcing layer covers said encapsulant material (at least) partially. For example, only a center portion and/or only peripheral portions of the encapsulant material main surface (external side) may be covered (directly or indirectly). This may provide the advantage that the architecture is more flexible, but still robust enough.

According to a further embodiment, the reinforcing layer is configured to cover a central portion of the encapsulant material, and wherein the encapsulant material is at least partially not covered by said reinforcing layer, in particular at least in a peripheral portion. Thereby, the design flexibility of the reinforcing portion may be highly improved and adapted to the individual requirements. In an example, a (full) ring-shaped frontal periphery of the encapsulant material is not covered by the reinforcing layer. This may provide the advantage that the architecture is more flexible, but still robust enough.

According to a further embodiment, the component carrier comprises a stack comprising at least one electrically insulating layer structure and/or a plurality electrically conductive layer structures, in particular stacked alternatingly. Accordingly, the described approach may be suitable for a multi-layer component carrier, wherein the central structure may form the core. Further electrically insulating layer structures (dielectric layer structures) may be stacked (by lamination) above and/or below the central structure (layer build-up).

According to a further embodiment, between the at least one component and the reinforcing portion, only the encapsulant material and/or the electrically insulating layer structure is/are provided. This may provide the advantage that the reinforcing portion may fulfill the stabilization effect especially efficiently by being close to the location of action. While in one example (see FIGS. 1 to 3) the component is covered by the encapsulant material, in another embodiment, the encapsulant material may only cover (a portion of) the sidewalls of the component and the top of the component may be covered by a further electrically insulating material.

According to a further embodiment, the reinforcing portion is provided at the same vertical position (level) (with respect to the stack thickness direction) of at least one portion of one of the plurality of electrically conductive layer structures. This structural feature may reflect a manufacturing step of providing the electrically conductive layer structure and the reinforcing portion in the same process step, in particular forming an electrically conductive layer structure as the reinforcing portion. This may provide the advantage of a reduction of manufacturing steps.

According to a further embodiment, the reinforcing portion/layer has the same thickness as the electrically conductive structure (on the same vertical level). According to a further embodiment, the reinforcing portion/layer has a different thickness (thinner or thicker) than the electrically conductive structure.

According to a further embodiment, the reinforcing layer is arranged on the same vertical level as the electrically conductive layer structure that is arranged directly on top of the central structure.

According to a further embodiment, the reinforcing layer is arranged on the same vertical level as an electrically conductive layer structure that is not directly arranged on top of the central structure (e.g. one or more electrically conductive layer structure may be arranged in between).

Accordingly, there is a high flexibility in designs regarding the vertical height of the reinforcing layer.

According to a further embodiment, the reinforcing portion externally extends beyond the vertical position of one of the two (upper and lower) main surfaces of the central structure.

According to a further embodiment, the reinforcing portion externally extends beyond the vertical position of both two main surfaces of the central structure. Thereby, an especially robust stabilization may be obtained.

According to a further embodiment, at least one central structure main surface is flush with at least one encapsulant material main surface.

According to a further embodiment, the reinforcing portion monolithically extends from the encapsulant material beyond the vertical position of (at least) one of the two main surfaces of the central structure. This structural feature may reflect (footprint) the manufacturing step of providing excessive encapsulant material (on the recess) followed by removing the excess material (e.g. by the grinding and/or etching).

According to a further embodiment, it has been surprisingly found by the inventors that additional encapsulation material that exceeds the (already filled) recess may improve the resilience against undulation/warpage. After application of the encapsulation material, the exceeding material may be (at least partially) removed. In case of complete removal, the main surfaces of encapsulation material and central structure may be equal. However, in case that the exceeding material is only removed partially, the vertical height of the encapsulation material may higher than of the central structure, which architecture may be especially efficient and robust.

According to a further embodiment, the encapsulant material externally extends beyond the vertical position of one of the two main surfaces of the central structure. According to a further embodiment, the encapsulant material externally extends beyond the vertical position of both two main surfaces of the central structure.

In other words, a thickness of the encapsulant material is larger than a thickness of the central structure (in a specific region). It has been surprisingly found by the inventors that such a high thickness of the encapsulant material (extending beyond at least one main surface of the central structure) may significantly reduce the risk of undulation and/or warpage.

Such a structural feature may further reflect a manufacturing step of (footprint) etching after the encapsulation.

According to a further embodiment, the reinforcing portion is configured as a portion of the encapsulant material that extends beyond the main surface of the central structure. The reinforcing portion may be in direct contact with the electrically conductive layer structure.

The above-described features may cover both cases, where the reinforcing portion is configured as the extended encapsulant material or as a metal layer.

According to a further embodiment, the external side of the encapsulant material is provided at the same vertical position as one of the plurality of electrically conductive layer structures. In particular, to the electrically conductive layer structure directly provided on the central structure main surface. This embodiment may reflect a manufacturing step of removing material, e.g. grinding, done after the encapsulant material and the electrically conductive layer structure have been provided.

According to a further embodiment, at least one connection area is provided on the at least one component. In particular, the connection area is formed on the opposite side (of the central structure) to the side (of the central structure) where the encapsulant material and/or the reinforcing portion are provided (exposed). In the present document, the term “connection area” may in particular refer to an electric connection element, for example a terminal or a pad. In this manner, the encapsulated component may be electrically connected to a conductive structure of the stack or another entity. Providing the reinforcing portion on the opposite side of the connection area may enable a highly efficient reinforcement, while the connection area is accessible (in a flexible manner) without removing part of the reinforcing portion.

According to a further embodiment, the reinforcing layer is one of the plurality of the electrically conductive layer structures, in particular the closest (along the component carrier thickness direction) electrically conductive layer structure with respect to the side of the component that is opposite to the at least one connection area. This may provide the advantage that the reinforcing portion/layer can be formed as one of the electrically conductive layer structures, i.e. essentially without further effort within the same manufacturing step, so that costs and effort can be saved.

According to a further embodiment, at least one electrically conductive interconnection (in particular a vertical interconnection access, via) is provided at the stack, the at least one electrically conductive interconnection being configured to pass through the central structure. The via may be configured as a blind hole or through-hole. Further, the via may be completely filled with electrically conductive material or only partially filled with electrically conductive material (e.g. plated sidewalls). In the latter case, the remaining part of the via may be filled with dielectric material and/or electrically conductive material, e.g. sinter paste. This may provide the advantage that established component carrier technology (e.g. via formation) may be directly implemented.

According to a further embodiment, the at least one electrically conductive interconnection is electrically connected to one of the electrically conductive layer structures, the electrically conductive layer structure being at the same vertical level (in the stack direction) of the reinforcing portion. The via may be configured as a through hole that electrically (and/or thermally) connects a first electrically conductive layer structure on top of the central structure with a second electrically conductive layer structure below the central structure.

According to a further embodiment, the reinforcing portion/layer is electrically connected to further electrically conductive structures of the component carrier (e.g. the electrically conductive interconnection) or the reinforcing portion/layer is not electrically connected to further electrically conductive structures of the component carrier.

According to a further embodiment a dielectric layer is provided on (at least) one side of the central structure, in particular wherein a further dielectric layer is provided on the opposite side of the central structure, more in particular covering the reinforcing layer and/or the encapsulant material. The dielectric layer may be an electrically insulating layer structure of the stack. In a preferred example, the dielectric layer is free of (reinforcing) fibers. In an example, the dielectric layer may comprise (reinforcing) (glass) spheres, e.g. ABFR material. This may provide the advantage that a layer build-up on top/bottom of the central structure can be efficiently performed, thereby further embedding the encapsulated component.

According to a further embodiment, more than one component, in particular two components or more, are arranged in the recess and are encapsulated by the encapsulant material. This may significantly increase the design-flexibility. As discussed above, a comparably large component may increase the risk of undulation/warpage. The same holds true for the application of two or more components. Nevertheless, using the described approach, even in case of two or more encapsulated components, undulation/warpage may be efficiently reduced.

According to a further embodiment of the method, the reinforcing portion comprises a reinforcing layer, and wherein the reinforcing layer has a stiffness greater than that of the encapsulant material.

According to a further embodiment of the method, the component carrier is manufactured by forming a stack comprising at least one electrically insulating layer structure and a plurality electrically conductive layer structures, in particular wherein one of the plurality electrically conductive layer structures comprises the reinforcing layer. This may provide the advantage that the described manufacturing method may be directly implemented into existing production lines with essentially no additional efforts.

According to a further embodiment of the method, the reinforcing layer is provided directly on the encapsulant material.

According to a further embodiment of the method, the reinforcing portion monolithically extends from the encapsulant material beyond the vertical position of one of the two main surfaces of the central structure.

According to a further embodiment of the method, the provision of the encapsulant material in the recess is configured so that the encapsulant material extends beyond the vertical position of one of the two main surfaces of the central structure, in particular the encapsulant material externally extends beyond the vertical position of both two main surfaces of the central structure.

According to a further embodiment, the method comprises: planarly removing, in particular by grinding, a portion of the encapsulant material extending beyond the vertical position of one or both the main surfaces of the central structure. Alternatively, a portion of the encapsulant material, which horizontal extension is limited by the horizontal extension of the recess, may be planarly removed, in particular by grinding. This step may result in at least one portion of the encapsulant exceeding the respective main surface of the central structure (having the external surface of said portion parallel said central structure main surface).

According to a further embodiment of the method, at least one electrically conductive layer structure is provided before the provision of the encapsulant material. In particular, the at least one electrically conductive layer structure is provided on the central structure. In a further step (after providing the encapsulant material) a further electrically conductive layer structure may be provided on top of the electrically conductive layer structure and the encapsulant material, thereby providing the reinforcing portion.

According to a further embodiment of the method, the step of planarly removing the portion of the encapsulant material additionally removes a portion of the at least one electrically conductive layer structure.

According to a further embodiment of the method, an etching step is provided after the provision of the encapsulant material and/or after the provision of the at least one electrically conductive layer structure. This step may affect at least one of the surface of the encapsulant material, the electrically conductive structure, the reinforcing portion, the central structure, e.g. by decreasing the thickness thereof.

According to an embodiment, the described component carrier (manufacturing method) may provide at least one of the following advantages: i) fine line/spacing is possible on the next layers which would not be possible to structure, when the component carrier is undulated; ii) the metal (copper) thickness on top of the component would be thinner than the metal thickness on top of the remaining portion of central structure, e.g. the core. A thinner metal layer may allow a finer line/space configuration in a particular area.

In an embodiment, the component carrier is configured as one of a printed circuit board, a substrate (in particular an IC substrate), and an interposer.

In an embodiment, the component carrier is shaped as a plate. This contributes to the compact design, wherein the component carrier nevertheless provides a large basis for mounting components thereon. Furthermore, in particular a naked die as an example of an embedded electronic component, can be conveniently embedded, thanks to its small thickness, into a thin plate such as a printed circuit board.

In an embodiment, the component carrier stack comprises at least one electrically insulating layer structure and at least one electrically conductive layer structure. For example, the component carrier may be a laminate of the mentioned electrically insulating layer structure(s) and electrically conductive layer structure(s), in particular formed by applying mechanical pressure and/or thermal energy. The mentioned stack may provide a plate-shaped component carrier capable of providing a large mounting surface for further components and being nevertheless very thin and compact.

In the context of the present application, the term “printed circuit board” (PCB) may particularly denote a plate-shaped component carrier which is formed by laminating several electrically conductive layer structures with several electrically insulating layer structures, for instance by applying pressure and/or by the supply of thermal energy. As preferred materials for PCB technology, the electrically conductive layer structures are made of copper, whereas the electrically insulating layer structures may comprise resin and/or glass fibers, so-called prepreg or FR4 material. The various electrically conductive layer structures may be connected to one another in a desired way by forming holes through the laminate, for instance by laser drilling or mechanical drilling, and by partially or fully filling them with electrically conductive material (in particular copper), thereby forming vias or any other through-hole connections. The filled hole either connects the whole stack, (through-hole connections extending through several layers or the entire stack), or the filled hole connects at least two electrically conductive layers, called via. Similarly, optical interconnections can be formed through individual layers of the stack in order to receive an electro-optical circuit board (EOCB). Apart from one or more components which may be embedded in a printed circuit board, a printed circuit board is usually configured for accommodating one or more components on one or both opposing surfaces of the plate-shaped printed circuit board. They may be connected to the respective main surface by soldering. A dielectric part of a PCB may be composed of resin with reinforcing fibers (such as glass fibers).

In the context of the present application, the term “substrate” may particularly denote a small component carrier. A substrate may be a, in relation to a PCB, comparably small component carrier onto which one or more components may be mounted and that may act as a connection medium between one or more chip(s) and a further PCB. For instance, a substrate may have substantially the same size as a component (in particular an electronic component) to be mounted thereon (for instance in the case of a Chip Scale Package (CSP)). In another embodiment, the substrate may be substantially larger than the assigned component (for instance in a flip chip ball grid array, FCBGA, configuration). More specifically, a substrate can be understood as a carrier for electrical connections or electrical networks as well as component carrier comparable to a printed circuit board (PCB), however with a considerably higher density of laterally and/or vertically arranged connections. Lateral connections are for example conductive paths, whereas vertical connections may be for example drill holes. These lateral and/or vertical connections are arranged within the substrate and can be used to provide electrical, thermal, and/or mechanical connections of housed components or unhoused components (such as bare dies), particularly of IC chips, with a printed circuit board or intermediate printed circuit board. Thus, the term “substrate” also includes “IC substrates”. A dielectric part of a substrate may be composed of resin with reinforcing particles (such as reinforcing spheres, in particular glass spheres).

The substrate or interposer may comprise or consist of at least a layer of glass, silicon (Si) and/or a photoimageable or dry-etchable organic material like epoxy-based build-up material (such as epoxy-based build-up film) or polymer compounds (which may or may not include photo-and/or thermosensitive molecules) like polyimide or polybenzoxazole.

In an embodiment, the at least one electrically insulating layer structure (dielectric layer) comprises at least one of the group consisting of a resin or a polymer, such as epoxy resin, cyanate ester resin, benzocyclobutene resin, bismaleimide-triazine resin, polyphenylene derivate (e.g. based on polyphenylenether, PPE), polyimide (PI), polyamide (PA), liquid crystal polymer (LCP), polytetrafluoroethylene (PTFE) and/or a combination thereof. Reinforcing structures such as webs, fibers, spheres or other kinds of filler particles, for example made of glass (multilayer glass) in order to form a composite, could be used as well. A semi-cured resin in combination with a reinforcing agent, e.g. fibers impregnated with the above-mentioned resins is called prepreg. These prepregs are often named after their properties e.g. FR4 or FR5, which describe their flame-retardant properties. Although prepreg particularly FR4 are usually preferred for rigid PCBs, other materials, in particular epoxy-based build-up materials (such as build-up films) or photoimageable dielectric materials, may be used as well. For high-frequency applications, high-frequency materials such as polytetrafluoroethylene, liquid crystal polymer and/or cyanate ester resins, may be preferred. Besides these polymers, low temperature cofired ceramics (LTCC) or other low, very low or ultra-low DK materials may be applied in the component carrier as electrically insulating structures.

In an embodiment, the at least one electrically conductive layer structure (for example electric interconnection, terminal, pad, via, etc.) comprises at least one of the group consisting of copper, aluminum, nickel, silver, gold, palladium, tungsten, magnesium, carbon, (in particular doped) silicon, titanium, and platinum. Although copper is usually preferred, other materials or coated versions thereof are possible as well, in particular materials coated with supra-conductive material or conductive polymers, such as graphene or poly(3,4-ethylenedioxythiophene) (PEDOT), respectively.

At least one further component may be embedded in and/or surface mounted on the stack.

The component and/or the at least one further component can be selected from a group consisting of an electrically non-conductive inlay, an electrically conductive inlay (such as a metal inlay, preferably comprising copper or aluminum), a heat transfer unit (for example a heat pipe), a light guiding element (for example an optical waveguide or a light conductor connection), an electronic component, or combinations thereof. An inlay can be for instance a metal block, with or without an insulating material coating (IMS-inlay), which could be either embedded or surface mounted for the purpose of facilitating heat dissipation. Suitable materials are defined according to their thermal conductivity, which should be at least 2 W/mK (milliKelvin). Such materials are often based, but not limited to metals, metal-oxides and/or ceramics such as for instance copper, aluminum oxide (Al₂O₃) or aluminum nitride (AIN). In order to increase the heat exchange capacity, other geometries with increased surface area are frequently used as well. Furthermore, a component can be an active electronic component (having at least one p-n-junction implemented), a passive electronic component such as a resistor, an inductance, or capacitor, an electronic chip, a storage device (for instance a DRAM or another data memory), a filter, an integrated circuit (such as field-programmable gate array (FPGA), programmable array logic (PAL), generic array logic (GAL) and complex programmable logic devices (CPLDs)), a signal processing component, a power management component (such as a field-effect transistor (FET), metal-oxide-semiconductor field-effect transistor (MOSFET), complementary metal-oxide-semiconductor (CMOS), junction field-effect transistor (JFET), or insulated-gate field-effect transistor (IGFET), all based on semiconductor materials such as silicon carbide (SIC), gallium arsenide (GaAs), gallium nitride (GaN), gallium oxide (Ga₂O₃), indium gallium arsenide (InGaAs), indium phosphide (InP) and/or any other suitable inorganic compound), an optoelectronic interface element, a light emitting diode, a photocoupler, a voltage converter (for example a DC/DC converter or an AC/DC converter), a cryptographic component, a transmitter and/or receiver, an electromechanical transducer, a sensor, an actuator, a microelectromechanical system (MEMS), a microprocessor, a capacitor, a resistor, an inductance, a battery, a switch, a camera, an antenna, a logic chip, and an energy harvesting unit. However, other components may be embedded in the component carrier. For example, a magnetic element can be used as a component. Such a magnetic element may be a permanent magnetic element (such as a ferromagnetic element, an antiferromagnetic element, a multiferroic element or a ferrimagnetic element, for instance a ferrite core) or may be a paramagnetic element. However, the component may also be an IC substrate, an interposer, or a further component carrier, for example in a board-in-board configuration. The component may be surface mounted on the component carrier and/or may be embedded in an interior thereof. Moreover, other components, in particular those which generate and emit electromagnetic radiation and/or are sensitive with regard to electromagnetic radiation propagating from an environment, may be used as a component or components.

In an embodiment, the component carrier is a laminate-type component carrier. In such an embodiment, the component carrier is a compound of multiple layer structures which are stacked and connected together by applying a pressing force and/or heat.

After processing interior layer structures of the component carrier, it is possible to cover (in particular by lamination) one or both opposing main surfaces of the processed layer structures symmetrically or asymmetrically with one or more further electrically insulating layer structures and/or electrically conductive layer structures. In other words, a build-up may be continued until a desired number of layers is obtained.

After having completed formation of a stack of electrically insulating layer structures and electrically conductive layer structures, it is possible to proceed with a surface treatment of the obtained layers structures or component carrier.

In particular, an electrically insulating solder resist may be applied to one or both opposing main surfaces of the layer stack or component carrier in terms of surface treatment. For instance, it is possible to form such a solder resist on an entire main surface and to subsequently pattern the layer of solder resist so as to expose one or more electrically conductive surface portions which shall be used for electrically coupling the component carrier to an electronic periphery. The surface portions of the component carrier remaining covered with solder resist may be efficiently protected against oxidation or corrosion, in particular surface portions containing copper.

It is also possible to apply a surface finish selectively to exposed electrically conductive surface portions of the component carrier in terms of surface treatment. Such a surface finish may be an electrically conductive cover material on exposed electrically conductive layer structures (such as pads, conductive tracks, etc., in particular comprising or consisting of copper) on a surface of a component carrier. If such exposed electrically conductive layer structures are left unprotected, then the exposed electrically conductive component carrier material (in particular copper) might oxidize, making the component carrier less reliable. A surface finish may then be formed for instance as an interface between a surface mounted component and the component carrier. The surface finish has the function to protect the exposed electrically conductive layer structures (in particular copper circuitry) and enable a joining process with one or more components, for instance by soldering. Examples for appropriate materials for a surface finish are Organic Solderability Preservative (OSP), Electroless Nickel Immersion Gold (ENIG), Electroless Nickel Immersion Palladium Immersion Gold (ENIPIG), Electroless Nickel Electroless Palladium Immersion Gold (ENEPIG), gold (in particular hard gold), chemical tin (chemical and electroplated), nickel-gold, nickel-palladium, etc. Also nickel-free materials for a surface finish may be used, in particular for high-speed applications. Examples are ISIG (Immersion Silver Immersion Gold), and EPAG (Electroless Palladium Autocatalytic Gold).

### BRIEF DESCRIPTION OF THE DRAWINGS

The aspects defined above and further aspects of the disclosure are apparent from the examples of embodiment to be described hereinafter and are explained with reference to these examples of embodiment.

FIG. 1, FIG. 2, FIG. 3, and FIG. 4 respectively illustrate a component carrier according to an example embodiment of the present disclosure.

FIG. 5 illustrates a conventional circuit board.

FIG. 6A, FIG. 6B, FIG. 6C, FIG. 6D, and FIG. 6E illustrate a conventional method of manufacturing the circuit board.

FIG. 7A, FIG. 7B, FIG. 7C, FIG. 7D, FIG. 7E, and FIG. 7F illustrate a method of manufacturing a component carrier according to an example embodiment of the present disclosure.

### DETAILED DESCRIPTION OF THE ILLUSTRATED EMBODIMENTS

The illustrations in the drawings are schematically presented. In different drawings, similar or identical elements are provided with the same reference signs.

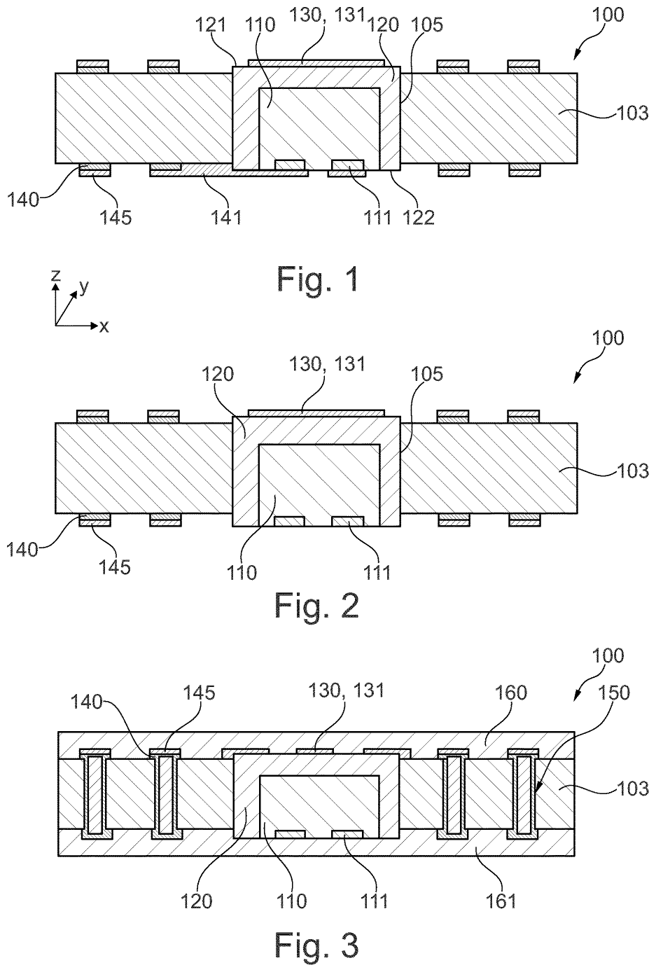

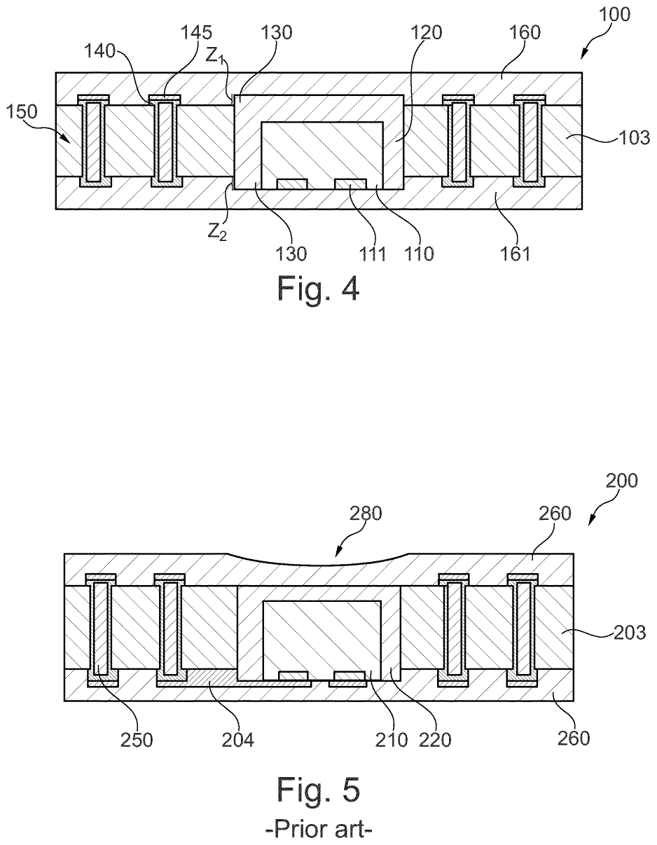

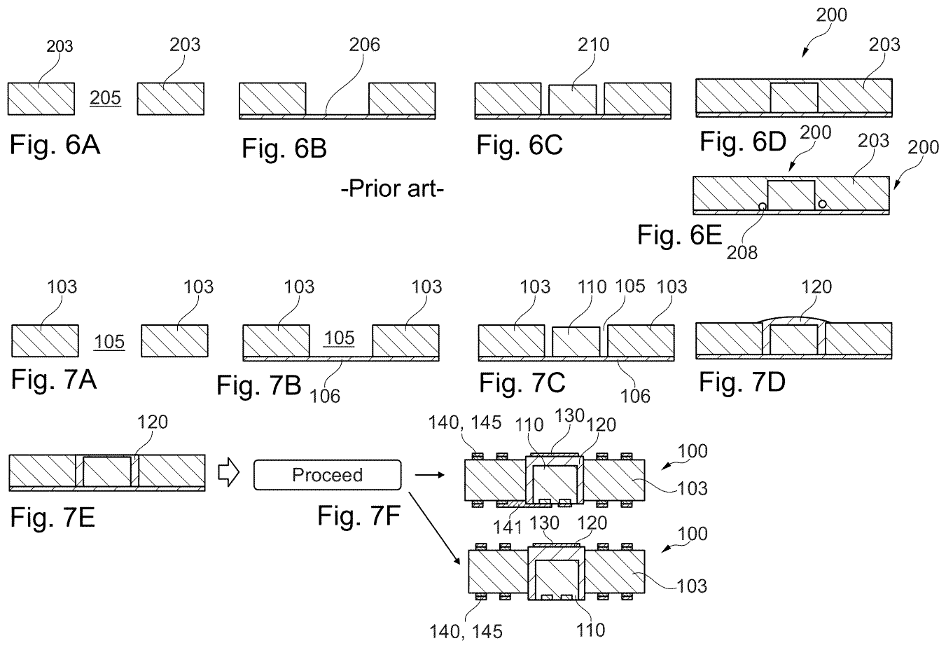

FIG. 1 shows a component carrier 100 according to an example embodiment of the disclosure. The component carrier 100 comprises a central structure 103 being in this example a thick core (layer structure), for example fully cured FR4. A recess 105 in the form of a through-hole has been formed through the central structure 103 and extends from the upper main surface of the central structure 103 through the thickness (along the vertical direction z) of the central structure 103 to the lower main surface of the central structure 103.

A component 110, in this example an active electronic component being an integrated circuit, is arranged in the recess 105. The component 110 comprises two electric connection areas (terminals/pads) 111 at an outer main surface. Hereby, the component 110 is arranged in the recess 105 such that said connection areas 111 are exposed and electrically connectable at the lower main surface of the central structure 103.

The component carrier 100 further comprises an encapsulant material 120, for example a resin such a non-reinforced or a non-fiber-reinforced resin. The encapsulant material 120 is provided in the recess 105 to thereby encapsulate the component 110. Specifically, the encapsulant material 120 fills the space between the component 110 and the sidewalls of the central structure 103 completely that define the recess 105. Further, the encapsulant material 120 covers the upper main surface of the component 110, which upper main surface is opposed to the lower main surface that comprises the connection areas 111. The lower main surface of the component 110 is not covered by the encapsulant material 120 in this example, so that the connection areas 111 are exposed and electrically connectable. It is indicated in FIG. 1 that the encapsulant material 120 comprises a first main surface 121 (upper main surface) and a second main surface 122 (lower main surface). These main surfaces 121, 122 can be considered as external sides of the encapsulant material 120.

Further, the component carrier 100 comprises a reinforcing portion 130, for example an electrically conductive material, preferably a metal such as copper. The reinforcing portion 130 comprises a stiffness being greater than a stiffness of the encapsulant material 120. The reinforcing portion 130 is associated (here connected) with the external side of the encapsulant material 120. In the embodiment of FIG. 1, reinforcing portion 130 is arranged directly on the first main surface 121 of the encapsulant material 120. In particular, the reinforcing portion 130 is configured as a reinforcing layer 131 arranged in the center of the first main surface 121 of the encapsulant material 120. Thereby, the peripheral portions (being closer to the edge/sidewall of the component 110 than to the center portion on the component 110) of the first main surface 121 of the encapsulant material 120 are free (not covered, exposed) of the reinforcing layer 131.

The encapsulant material 120 extends vertically (along z) beyond the upper main surface of the central structure 103 and beyond the lower main surface of the central structure 103. The reinforcing portion 130 extends vertically beyond the upper main surface of the central structure 103.

The recess 105 can define a first frontal area and the reinforcing layer 131 can define a second frontal area (when seen from above, i.e. along the z-axis), the second frontal area has an area value of around 80% with respect to the area value of the first frontal area (in this example). The reinforcing portion 130 monolithically extends from the encapsulant material 120 beyond the vertical position of one of the two main surfaces of the central structure 103.

The component carrier 100 preferably comprises a stack with a plurality of electrically insulating layer structures (not shown) and electrically conductive layer structures 104. The central structure 103 can be configured as the core layer structure of such a stack (not shown). At the upper main surface and at the lower main surface of the central structure 103, respectively, there is arranged a first electrically conductive layer structure 140 (directly on the central structure 103) and a second electrically conductive layer structure 145 (on top of the first electrically conductive layer structure 140). The electrically conductive layer structures 140, 145 are configured as separate islands within the same layer at the same vertical height.

The connection areas 111 of the encapsulated component 110, exposed at the second main surface of the encapsulant material 120, are electrically connected (indicated by reference sign 141) to the electrically conductive layer structures 140, 145 at the lower main surface of the central structure 103.

In this example, the reinforcing layer 131 is formed on the same vertical height as the second electrically conductive layer structure 145 on the upper main surface of the central structure 103 (and the first main surface of the encapsulant material 120). The upper portion of the encapsulant material 120 is further arranged at the same vertical height as the first electrically conductive layer structure 140. The exposed portions of the electrically conductive layer structures 140, 145 and/or reinforcing portion 130 may comprise a surface finish e.g. gold or solder resist.

FIG. 2 shows a component carrier 100 according to a further example embodiment of the disclosure. The component carrier 100 is very similar to the one described for FIG. 1 above. The difference is that in the component carrier 100 of FIG. 2, the encapsulated component 110 is not connected at its connection areas 111 to the electrically conductive layer structures 140, 145 of the stack (asymmetric (copper plating) instead of symmetric (plating) in case of FIG. 1). Instead, the connection areas 111 are exposed (preferably on the same vertical level (along z) as the second electrically conductive layer structure 145) and can be connected for example to another entity such as electrical connections of an interposer device and/or another component carrier. Accordingly, the encapsulant material 120 is only associated with (here in physical contact with) the reinforcing portion 130 and not with additional electrically conductive layer structures 140, 145 (that may comprise the same material as the reinforcing portion 130). Further, the second main surface 122 (lower main surface) may be at the same vertical level (along z) as the second electrically conductive layer structure 145.

FIG. 3 shows a component carrier 100 according to a further example embodiment of the disclosure. In this example, there is shown the stack, comprising (in addition to the central structure 103) at least one electrically insulating layer structure (here dielectric layer structure 160) arranged on top of the central structure 103 and at least one further dielectric layer structure 161 arranged below the central structure 103. In this manner, the reinforcing portion 130 and/or the connection areas 111 of the encapsulated component 110 are embedded (buried) in the dielectric material 160, 161. In a further step, the connection areas 111 can be exposed again, e.g. by drilling respective holes through the further dielectric layer structure 161.

The component carrier 100 comprises a plurality of electrically conductive interconnections 150 (vias) provided in the stack, wherein the electrically conductive interconnections 150 are configured to pass through the central structure 103 (as through-holes, completely or partially filled with electrically conductive material). The electrically conductive interconnections 150 are respectively electrically connected to the electrically conductive layer structures 140, 145. The electrically conductive layer structure 140, 145 are in this example at the same vertical level as the reinforcing portion 130.

Further, in this example, the reinforcing layer 131 is configured so that the center of the encapsulant material (upper) main surface 121 and the peripheral portions are covered. Yet, portions between the center portion and the peripheral portions are not covered by the reinforcing layer 131.

The peripheral portions of the reinforcing layer/portion 130, 131 extend over the vertical extension of the recess 105. Thereby, at least part of those peripheral portions are thicker (higher in vertical (z-) direction) compared to the central portion of the reinforcing layer/portion 130, 131. These described thicknesses may also be referenced to the height level of the first electrically conductive layer structure 140 and second electrically conductive layer structure 145.

FIG. 4 shows a component carrier 100 according to a further example embodiment of the disclosure. In this example, the reinforcing portion is configured as a portion of the encapsulant material 120 and not as a reinforcing layer 131. Accordingly, the reinforcing portion 130 is this example is formed as an electrically insulating material and not as a metal. The reinforcing portion 130 is here specifically the portion of the encapsulant material 120 that extends beyond (in the vertical direction) the main surface of the central structure 103. In this example, there are two reinforcing portions 130, the first extends beyond the upper main surface of the central structure 103, and the second extends beyond the lower main surface of the central structure 103. The vertical difference between encapsulating material 120 and main surface of central structure 103, which defines the reinforcing portion 130, is indicated by reference signs Z1 and Z2. In this example the length of Z1 and Z2 are different. In a further example, the length of Z1 and Z2 may be the same.

FIG. 7A, FIG. 7B, FIG. 7C, FIG. 7D, FIG. 7E, and FIG. 7F illustrate a method of manufacturing a component carrier 100 according to an example embodiment of the present disclosure.

In FIG. 7A a recess 105 (here a through hole) is provided in a central structure 103 being a thick core.

In FIG. 7B a temporary carrier 106, e.g. an adhesive foil, is arranged below the central structure 103 and the recess 105.

In FIG. 7C a component 110 is placed onto the temporary carrier 106 and within the recess 105 (e.g. fixed by an adhesive).

In FIG. 7D the component 110 is embedded within the recess 105 by an encapsulant material 120, in particular being different from the central structure 103 material, by a “plug-in” technique. The encapsulant material 120 forms, after filling the space between recess sidewalls and component 110, a hump (exceeding material) over the component region.

In FIG. 7E the hump is removed, e.g. by grinding, to provide a flush main surface between central structure 103 and encapsulant material 120 or to provide a vertically extending encapsulant material portion.

In FIG. 7F the temporary carrier 106 is removed and electrically conductive layer structures 140, 145 are formed at the upper and lower main surfaces of the central structure 103. A specific one of said electrically conductive layer structures is configured as a reinforcing portion 130, in particular a reinforcing layer 131, associated with the external side (here upper main surface) of the encapsulant material 120. A step of (flash) etching is applied to the central structure 103, so that there is no flush top surface between the central structure 103 and encapsulant material 120 (instead, the encapsulant material 120 comprises a greater thickness). The yielded component carriers 100 in this example are for example those described in detail for FIGS. 1 and 2 above.

### REFERENCE SIGNS

100 Component carrier
103 Central structure, core layer structure
104 electrically conductive layer structures
105 Recess
106 Temporary carrier
110 Component
111 Connection area
120 Encapsulant material
121 First encapsulant material external side
122 Second encapsulant material external side
130 Reinforcing portion
131 Reinforcing layer
140 First electrically conductive layer structure
141 Electrical connection to component
145 Second electrically conductive layer structure
150 Electrically conductive interconnection, Via
160 Dielectric layer
161 Further dielectric layer
200 Conventional circuit board
203 Conventional core
204 Conventional electric connection
205 Conventional cavity
206 Conventional temporary carrier
208 Undesired void
210 Conventional component
220 Conventional mold
250 Conventional via
260 Conventional dielectric layer
280 Undesired undulation effect

1. A component carrier, comprising:
a central structure having a recess extending from a main surface through the thickness of the central structure;
at least one component arranged in the recess;
an encapsulant material in the recess and at least partially encapsulating the at least one component; and
a reinforcing portion, wherein the reinforcing portion is associated with the external side of the encapsulant material.

2. The component carrier according to claim 1, wherein the central structure comprises a core layer structure, with a thickness in the range between 500 μm and 2 mm.

3. The component carrier according to claim 1, wherein the reinforcing portion comprises a reinforcing layer and wherein the reinforcing layer comprises a stiffness greather than that of the encapsulant material

4. The component carrier according to claim 3, wherein the recess defines a first frontal area and the reinforcing layer defines a second frontal area having an area value of at least 60 with respect to the area value of the first frontal area.

5. The component carrier according to claim 3, wherein the reinforcing layer comprises a metal.

6. The component carrier according to claim 3, wherein the reinforcing layer covers the encapsulant material at least partially.

7. (canceled)

8. The component carrier according to claim 1, further comprising:
a stack comprising at least one electrically insulating layer structure and a plurality of electrically conductive layer structures.

9. The component carrier according to claim 8, wherein, between the at least one component and the reinforcing portion only the encapsulant material and/or the at least one electrically insulating layer structure is provided.

10. (canceled)

11. The component carrier according to any claim 1, wherein the reinforcing portion externally extends beyond the vertical position of one of the two main surfaces of the central structure.

12. The component carrier according to claim 1, wherein the reinforcing portion monolithically extends from the encapsulant material beyond the vertical position of one of the two main surfaces of the central structure.

13. The component carrier according to any claim 1, wherein the encapsulant material externally extends beyond the vertical position of one of the two main surfaces of the central structure.

14. (canceled)

15. The component carrier according to claim 1, wherein at least one electrically conductive interconnection is provided at the stack, the at least one electrically conductive interconnection being configured to pass through the central structure.

16. The component carrier according to claim 15, wherein the at least one electrically conductive interconnection is electrically connected to at least one electrically conductive layer structures wherein the electrically conductive layer structure is at the same level vertical level of the reinforcing portion.

17. The component carrier according to claim 1, wherein more than one component is arranged in the recess and encapsulated by the encapsulant material.

18. A method of manufacturing a component carrier, the method comprising:
providing a central structure having a recess, wherein the recess extends from a main surface through the thickness of the central structure;
arranging at least one a component in the recess;
encapsulating the component by providing encapsulant material in the recess; and
providing a reinforcing portion wherein the reinforcing portion is associated with an external side of the encapsulant material.

19. The method of manufacturing a component carrier according to claim 18, wherein the reinforcing portion comprises a reinforcing layer and wherein the reinforcing layer has a stiffness higher than that of the encapsulant material.

20. The method according to claim 19, wherein the component carrier is manufactured by forming a stack comprising at least one electrically insulating layer structure and a plurality electrically conductive layer structures wherein one of said the plurality of electrically conductive layer structures comprises the reinforcing layer.

21. The method of manufacturing a component carrier according to claim 18, wherein the reinforcing portion monolithically extends from the encapsulant material beyond the vertical position of one of the two main surfaces of the central structure.

22. The method of manufacturing a component carrier according to claim 19, wherein the method comprises:
planarly removing a portion of the encapsulant material extending beyond the vertical position of one of the main surfaces of the central structure.

23.-24. (canceled)

25. The method of manufacturing a component carrier according to claim 20, wherein an etching step is provided after the provision of the encapsulant material and/or after the provision of the at least one electrically conductive layer structure.
